(19) United States
(12) Patent Application Publication
(10) Pub. No.: US 2009/0066360 A1
(43) Pub. Date: Mar. 12, 2009

(54) METHOD FOR DETERMINING AN INDUCTANCE OF A MOTOR

(75) Inventor: Stefan Kunzel, Erlangen (DE)

Correspondence Address: HENRY M FEIEREISEN, LLC;HENRY M FEIEREISEN, 708 THIRD AVENUE, SUITE 1501, NEW YORK, NY, 10017, US

(73) Assignee: Siemens Aktiengesellschaft, Munchen (DE)

(21) Appl. No.: 12/279,793

(22) PCT Filed: Dec. 28, 2006
(86) PCT No.: PCT/EP06/70252

§ 371 Date: Aug. 18, 2008

(30) Foreign Application Priority Data
Feb. 17, 2006 (DE) 10 2006 007 435.1

(51) Int. Cl. G01R 31/34

(52) U.S. Cl. 324/772

(57) ABSTRACT

The intention is to simplify the measurement of an inductance characteristic curve of a motor. To this end, provision is made for a current (i) having a non-periodic current offset component and a periodic current component to be injected into the motor's winding so that the motor accelerates. A corresponding voltage (u) across the winding is measured and a voltage interference component and a periodic voltage component are determined from the measurement. The inductance of the winding can finally be determined from these two components. It is thus possible to dispense with the operation of blocking the motor or to dispense with an expensive motor test rig in order to determine the inductance characteristic curve.

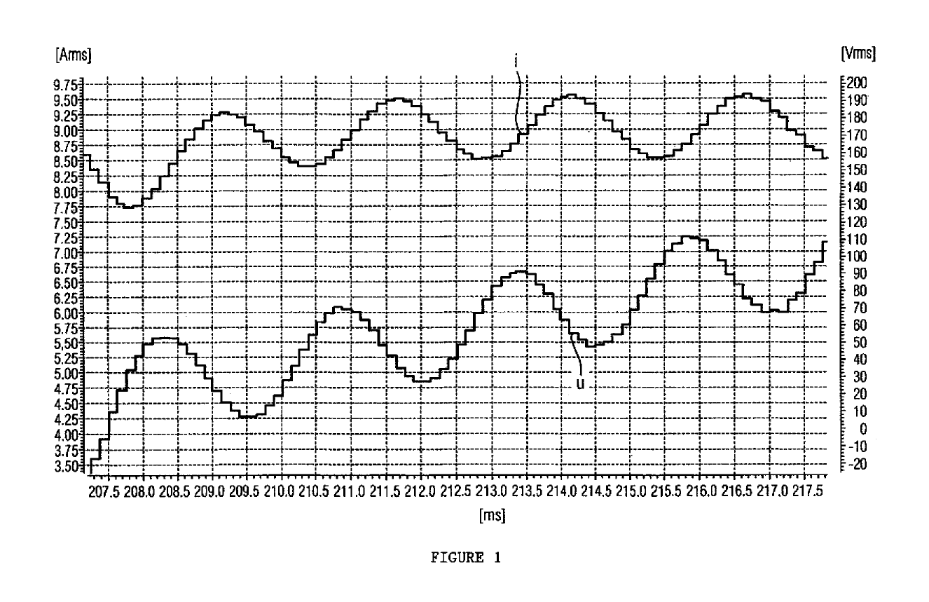

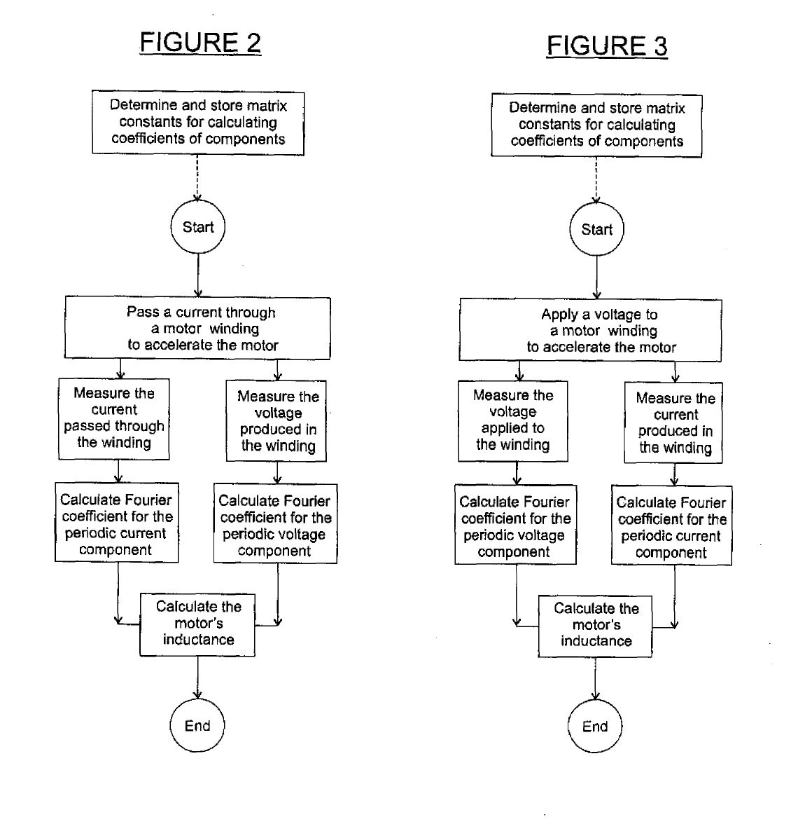

The present invention relates to a method for determining an inductance of a winding of an electric motor.

In order to adapt a current regulator of an electric motor, it is generally necessary to determine accurately the inductances and/or inductance profiles of the motor. Since the inductances are not constant variables but, inter alia, are current-dependent variables, correspondingly complex measurements are required. Until now, in order to measure a so-called q-inductance line, the motor has had to be stalled or has had to be kept at a constant rotation speed on a motor test rig. However, there are frequently no facilities to do this on site, since suitable test equipment is expensive. The measurement of the so-called q-inductance therefore plays a major role for current regulator adaptation because this inductance decreases as the current rises, thus requiring adaptation in the current regulator.

The object of the present invention is therefore to simplify the process of determining an inductance characteristic of an electric motor.

According to the invention, this object is achieved by a method for determining an inductance of a winding of an electric motor by passing current through the winding with a non-periodic current offset component and a periodic current component, such that the motor accelerates, by providing a voltage signal for the winding and determining a voltage disturbance component and a periodic voltage component from this, and determining the inductance of the winding from the periodic current component or a measured, periodic current signal and the periodic voltage component.

Alternatively, the object mentioned above is achieved with the aid of a method for determining an inductance of a winding of an electric motor by application of a voltage to the winding with a non-periodic voltage offset component and a periodic voltage component, such that the motor accelerates, by providing a current signal for a current through the winding and determining a current disturbance component and a periodic current component from this, and determining the inductance of the winding from the periodic current component and the periodic voltage component or a measured, periodic voltage signal.

The invention is based on the discovery that it is better to carry out the inductance measurement during acceleration since neither a stalling facility nor a motor test rig is often available. The aim is therefore to allow the q-inductance (inductance relating to the torque-forming current) to be measured during acceleration of the motor. For this purpose, a superimposed, sinusoidal alternating signal (torque-forming current) is applied to a q-current offset, and the Fourier coefficients of the associated signals are determined from the current actual value and the voltage actual value for the respective sinusoidal frequency. The q-inductance can be calculated from these coefficients. However, the q-voltage rises during the acceleration, so that there is a discontinuous transition between the initial value and the final value.

Discrete Fourier transformation or fast Fourier transformation (DFT or FFT) is normally used to determine the Fourier coefficients. In this case, the measured signals are implicitly continued periodically, and the frequency components of this signal produced in this way are determined. If a discontinuous transition occurs in this case between the initial value and the final value, the result is highly dominated by this discontinuity. Exact determination of the frequency components of this signal would not be possible from the DFT or FFT on its own. In order nevertheless to allow the frequency components to be determined despite these discontinuities, non-periodic disturbance components in the measured signal are estimated or determined. Only the periodic components of the signal are then used to determine the inductance.

The current or voltage disturbance components can also be estimated well by means of a polynomial, in particular a second-order polynomial. This makes it possible to separate the non-periodic component of the signals substantially from the periodic component.

According to one particularly preferred embodiment of the present invention, Fourier coefficients of the periodic current component and of the periodic voltage component are calculated in order to determine the inductance. This allows the specific profile of the inductance to be calculated very exactly.

The present invention will now be explained in more detail with reference to the attached drawing, which illustrates the current and voltage profile on a motor, in order to determine its inductance.

The exemplary embodiment described in more detail in the following text represents one preferred embodiment of the present invention.

In order to measure an inductance of a motor, a current i is applied to the motor, as is illustrated in the FIGURE. This current contains a non-periodic component and a periodic component. In this specific case, the sinusoidal component has a continuously rising offset component (actual value) superimposed on it, because of the acceleration. However, in principle, a constant offset component (nominal value) is desired.

In this specific example, the measured voltage u has the profile shown in the FIGURE. This is also characterized by a sinusoidal component on which a non-periodic component in the form of a ramp is superimposed. The non-periodic component of the voltage u in this case rises more sharply than the non-periodic part of the current i.

The measured current and voltage signals (actual values) can be represented by a signal model which models the expected disturbances (caused inter alia by the acceleration of the motor) and the sinusoidal signals. A signal model with a sine, cosine and a second-order polynomial can be used as one specific example. The polynomial contains the rising voltage (disturbance) during the acceleration of the motor. The factors in front of the sine and the cosine correspond to the sought Fourier coefficients when the disturbance model is removed from the signal (in this case the polynomial). The signal model can be applied for the current signal iq(t) and the voltage signal uq(t) as follows:

iq(t)=ki₀+ki₁·t+ki₂·t²+rei·cos(ω·t)+imi·sin(ω·t)

uq(t)=ku₀+ku₁·t+ku₂·t²+reu·cos(ω·t)+imu·sin(ω·t)

The aim is to calculate the inductance from these equations and the basic equation

$$Z = j ω L = \frac{U}{I} .$$

This is done by determining the coefficients rei, imi, reu and imu. In principle, these coefficients can also be obtained from nominal and actual values of the current and voltage signals.

In order to calculate all the coefficients of the signal model, more measurement points must be obtained than there are coefficients. In the present example, more than five measurement points must be determined in order to determine the coefficients of the current profile. However, considerably more measurement points will normally be determined, since the signals are generally noisy.

The above equations can be solved, for example, using the method of minimizing the error squares (Gaussian algorithm). In this case, in particular, the coefficients in front of the cosine and the sine are of interest because they correspond to the Fourier coefficients by means of which the inductance can be calculated.

The coefficients in the stated equations can even be calculated on-line, that is to say during the measurement, because of the comparatively small amount of computation complexity. If required, the necessary matrix inversion for calculation of the sought coefficients can be carried out in advance, that is to say off-line, and appropriate constants can be stored for calculation.

Sine components in measurement signals which cannot be continued periodically can therefore advantageously be determined in order to determine the inductance profiles. Specifically, the q-inductance characteristic can also be measured during acceleration of the motor. In consequence, there is no need to provide any additional mechanical components, such as a motor test rig or stalling device, for a measurement such as this. This type of motor data identification considerably simplifies motor commissioning.

1.-5. (canceled)

6. A method for determining an inductance of a winding of an electric motor comprising the steps of:
passing a current signal through the winding such that the motor accelerates, said current having a non-periodic current offset component and a periodic current component;
determining a voltage disturbance component and a periodic voltage component of a voltage signal produced when the current is applied to the winding; and
calculating an inductance of the winding using the periodic current component and the periodic voltage component.

7. The method of claim 6, wherein the periodic current component is a measured periodic current signal.

8. The method of claim 6, wherein the current disturbance component satisfies a polynomial.

9. The method of claim 8, wherein the current disturbance component satisfies a second-order polynomial.

10. The method of claim 6, wherein the voltage disturbance component satisfies a polynomial.

11. The method of claim 10, wherein the voltage disturbance component satisfies a second-order polynomial.

12. A method for determining an inductance of a winding of an electric motor comprising the steps of:
applying a voltage signal to the winding such that the motor accelerates, said voltage having a non-periodic voltage offset component and a periodic voltage component;
determining a current disturbance component and a periodic current component of a current signal produced when the voltage is applied to the winding; and
calculating an inductance of the winding using the periodic current component and the periodic voltage component.

13. The method of claim 12, wherein the periodic voltage component is a measured periodic voltage signal.

14. The method of claim 12, wherein the current disturbance component satisfies a polynomial.

15. The method of claim 14, wherein the current disturbance component satisfies a second-order polynomial.

16. The method of claim 12, wherein the voltage disturbance component satisfies a polynomial.

17. The method of claim 16, wherein the voltage disturbance component satisfies a second-order polynomial.

18. The method of claim 6, wherein the step of determining a voltage disturbance component and a periodic voltage component of the voltage signal produced when the current is passed through the winding includes calculating a Fourier coefficient of the periodic voltage component, said method further comprising the step of calculating a Fourier coefficient of the periodic current component for use in calculating the inductance.

19. The method of claim 6, wherein the step of determining an inductance of the winding uses coefficients of the periodic current component and the periodic voltage component, and the step of determining an inductance of the winding further comprises the steps of determining and storing constants of a matrix inversion used to calculate coefficients of the periodic current component and the periodic voltage component, and using the stored constants to calculate the coefficients of the periodic current component and the periodic voltage component used to calculate the inductance of the winding.

20. The method of claim 12, wherein the step of determining a current disturbance component and a periodic current component of the current signal produced when the voltage is applied to the winding includes calculating a Fourier coefficient of the periodic current component, further comprising the step of calculating a Fourier coefficient of the periodic voltage component for use in calculating the inductance.

21. The method of claim 12, wherein the step of determining an inductance of the winding uses coefficients of the periodic current component and the periodic voltage component, and the step of determining an inductance of the winding further comprises the steps of determining and storing constants of a matrix inversion used to calculate coefficients of the periodic current component and the periodic voltage component, and using the stored constants to calculate the coefficients of the periodic current component and the periodic voltage component used to calculate the inductance of the winding.
